(19) United States
(12) Patent Application Publication
(10) Pub. No.: US 2022/0148879 A1
(43) Pub. Date: May 12, 2022

(54) METHOD FOR TREATING PHOTORESIST AND SELF-ALIGNED DOUBLE PATTERNING METHOD

(71) Applicant: CHANGXIN MEMORY TECHNOLOGIES, INC., Hefei City (CN)

(72) Inventors: JUN XIA, Hefei (CN); Shijie BAI, Hefei (CN)

(73) Assignee: CHANGXIN MEMORY TECHNOLOGIES, INC., Hefei City (CN)

(21) Appl. No.: 17/389,511

(22) Filed: Jul. 30, 2021

Related U.S. Application Data
(63) Continuation of application No. PCT/CN2021/097375, filed on May 31, 2021.

(30) Foreign Application Priority Data
Nov. 11, 2020 (CN) 202011257944.9

(51) Int. Cl. H01L 21/033; H01L 21/027; G03F 7/40

(52) U.S. Cl. CPC H01L 21/0337; G03F 7/40; H01L 21/0274

(57) ABSTRACT

A method for treating the photoresist includes: developing the photoresist, forming a patterned photoresist layer on a mask material layer, and forming byproducts on the surface of the photoresist layer; and treating the photoresist layer with plasma to harden the photoresist layer.

### CROSS-REFERENCE TO RELATED APPLICATIONS

This application is a continuation of International Application No. PCT/CN2021/097375 filed on May 31, 2021, which claims priority to Chinese Patent Application No. 202011257944.9 filed on Nov. 11, 2020. The disclosures of these applications are hereby incorporated by reference in their entirety.

### BACKGROUND

With the rapid development of a semiconductor technology, the dimension of semiconductor structures is decreasing, and the integration level of integrated circuits is increasing. To increase the integration density of devices or circuits in semiconductor structures, an SADP method may be adopted for manufacturing.

### SUMMARY

The disclosure relates to the technical field of semiconductors, and in particular to a method for treating a photoresist and a Self-Aligned Double Patterning (SADP) method.

The disclosure provides a method for treating a photoresist and an SADP method for improving the yield of semiconductor structures.

To achieve the above object, the disclosure provides the following technical solutions.

In a first aspect, the disclosure provides a method for treating a photoresist. The photoresist is disposed on a mask material layer, and the mask material layer is disposed on a target etching layer. The method includes the following operations. The photoresist is developed to form a patterned photoresist layer on the mask material layer and to form byproducts on a surface of the photoresist layer. The photoresist layer is treated with plasma to harden the photoresist layer. The byproducts are removed at least partially.

In a second aspect, the disclosure also provides an SADP method, which includes the following operations. A target etching layer is provided. A mask material layer and a photoresist, which are sequentially stacked, are formed on the target etching layer. The photoresist is developed to form a patterned photoresist layer on the mask material layer and to form byproducts on a surface of the photoresist layer. The photoresist layer is treated with plasma to harden the photoresist layer. The byproducts are removed at least partially. The mask material layer is etched by taking the photoresist layer treated with plasma as a mask to form a mask layer with self-aligned double patterns.

### BRIEF DESCRIPTION OF THE DRAWINGS

FIG. 1 is a schematic structure diagram of a target etching layer, a mask material layer, and a photoresist according to an example of the disclosure.

FIG. 2 is a flowchart of a method for treating a photoresist according to an example of the disclosure.

FIG. 3 is a schematic structure diagram of a developed photoresist according to an example of the disclosure.

FIG. 4 is a schematic diagram of a photoresist treated with plasma according to an example of the disclosure.

FIG. 5 is a flowchart of an SADP method according to an example of the disclosure.

FIG. 6 is a schematic structure diagram of a mask material layer according to an example of the disclosure.

FIG. 7 is a schematic diagram of a structure with a sacrificial layer formed according to an example of the disclosure.

FIG. 8 is a schematic diagram of a structure with a side wall formed according to an example of the disclosure.

FIG. 9 is a schematic diagram of a structure with a side wall material layer formed according to an example of the disclosure.

FIG. 10 is a schematic diagram of a structure with a side wall material layer partially removed an example of the disclosure.

FIG. 11 is a schematic diagram of a structure with a first anti-reflection layer partially removed according to an example of the disclosure.

### DETAILED DESCRIPTION

To improve the integration density of devices or circuits in a semiconductor structure, the semiconductor structure may be manufactured by using an SADP method. The SADP method generally combines a patterning process and an etching process to form a semiconductor structure, and a mask layer with dense patterns may be formed through a photoresist layer with sparse patterns. A Critical Dimension (CD) of the semiconductor structure formed in a target etching layer is small by the SADP method, so that the integration density of the semiconductor structure can be improved.

A mask material layer and a photoresist layer are generally formed by stacking on a target etching layer. Then, the mask material layer is dry-etched by taking the photoresist layer as a mask to reserve the mask material layer covered by a photoresist, and a sacrificial layer is formed by the mask material layer reserved after etching. Thereafter, an oxide layer is formed on the sacrificial layer; the oxide layer and the sacrificial layer are partially removed by etching to reserve the oxide layer on a side face of the sacrificial layer before etching to form a mask layer with self-aligned double patterns. Then, the target etching layer is etched by taking the mask layer as a mask.

However, when the mask material layer is dry-etched by taking the photoresist layer as a mask, the photoresist layer is likely to deform, so that an etched pattern is deformed, processing errors of subsequent steps are continuously accumulated, and the yield of semiconductor structures is low.

A target etching layer, a mask material layer, and a photoresist are sequentially stacked, a patterned photoresist layer is formed after the photoresist is developed, then the mask material layer is etched by taking the photoresist layer as a mask to obtain a mask layer with self-aligned double patterns, and then the target etching layer is etched by taking the mask layer as a mask to form a required semiconductor structure.

Exemplarily, the photoresist is formed on the mask material layer. Then, the photoresist is exposed to change chemical components of the photoresist. Thereafter, the photoresist is partially removed by a developing solution, so that the photoresist is developed to obtain a patterned photoresist layer. The mask material layer is dry-etched by taking the photoresist layer as a mask to form a sacrificial layer. Thereafter, a filling layer is deposited on the sacrificial layer, the filling layer on a side wall of the sacrificial layer is reserved, the reserved filling layer forms a mask layer with self-aligned double patterns, and the mask layer serves as a mask for etching the target etching layer.

However, when the mask material layer is dry-etched by taking the photoresist layer as a mask, the dry etching temperature is high, so that the photoresist layer is likely to flow and deform, the problem of poor etching wiggling exists, thus affecting the etching accuracy of subsequent processes, and reducing the yield of semiconductor structures. On the other hand, byproducts are formed on a surface of the photoresist layer during development, the byproducts are located on the surface of the photoresist layer, gas in the photoresist layer is prevented from being discharged, and meanwhile, high pressure is exerted on the photoresist layer, so that the deformation of the photoresist layer is aggravated. Moreover, with the increase of the depth-to-width ratio of the photoresist layer, the deformation of the photoresist layer is increased, and the etching accuracy is further reduced.

According to the method for treating the photoresist provided by the disclosure, the photoresist layer formed after development is treated with plasma, so that the photoresist layer is hardened, and the deformation resistance of the photoresist layer during dry etching is improved. Meanwhile, the photoresist layer formed after development is treated with plasma, so that the byproducts on a surface of the photoresist layer can be at least partially removed, which is advantageous for the gas in the photoresist layer to be discharged, the stress of the photoresist layer is reduced, and the deformation resistance of the photoresist layer during dry etching is further improved, thereby causing high etching accuracy when the photoresist layer serves as a mask for dry etching, and finally improving the yield of semiconductor structures.

In order that the above objects, features, and advantages of the examples of the disclosure are more readily understood, the technical solutions in the examples of the disclosure will be clearly and completely described below with reference to the drawings in the examples of the disclosure. It is apparent that the described examples are only a part of the examples of the disclosure, not all of the examples. Based on the examples in the disclosure, all other examples obtained by those of ordinary skill in the art without involving any inventive effort are within the scope of protection of the disclosure.

### Example 1

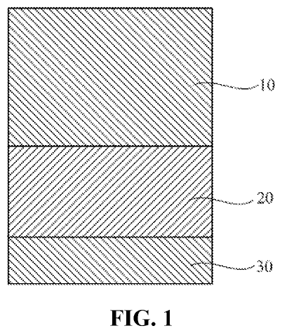

Referring to FIG. 1, a photoresist 11 may be formed on a mask material layer 20 by a spin coating process. The mask material layer 20 may be formed on a target etching layer 30 by a deposition process. The photoresist 11 generally includes components such as a polymer, a solvent, a photosensitive agent, and an additive, and has photosensitivity and etching blocking performance.

The mask material layer 20 serves to transfer patterns, and a mask layer with self-aligned double patterns is obtained through a process flow of etching, deposition, and etching. The mask layer serves as a mask for etching the target etching layer 30. The mask material layer 20 may be a multi-layers structure in which the layers are sequentially stacked.

The target etching layer 30 is different according to different semiconductor structures required to be formed. For example, when etching gate, the target etching layer 30 is a gate material layer disposed on a substrate. For example, the gate material layer is a polysilicon layer. When etching a metal connecting line, the target etching layer 30 is a dielectric layer. For example, the dielectric layer is a silicon oxide layer. The metal connecting line is formed in a pattern formed by etching the dielectric layer.

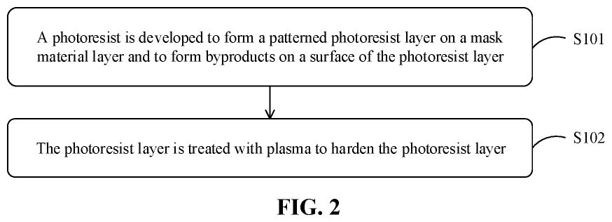

Referring to FIG. 2, FIG. 2 is a flowchart of a method for treating a photoresist according to an example of the disclosure. Through the method, the deformation resistance of the photoresist can be improved, and the deformation of the photoresist layer in a subsequent process flow such as dry etching is reduced to improve the yield of semiconductor structures. The method for treating the photoresist may specifically include the following operations.

In S101, the photoresist is developed to form a patterned photoresist layer on a mask material layer and to form byproducts on a surface of the photoresist layer.

It will be appreciated that, before the operation that the photoresist 11 is developed, the method for treating the photoresist 11 further includes: the photoresist 11 is baked and exposed.

The photoresist 11 is baked to evaporate the part of the solvent in the photoresist 11, so that the photoresist 11 and the mask material layer 20 have better adhesion performance, and on the other hand, the interference of the solvent in the photoresist 11 on the exposure process is reduced.

The exposure of the photoresist 11 may change the chemical property of the photoresist 11. The illuminated photoresist 11 and the non-illuminated photoresist 11 may have different chemical properties, so that the illuminated photoresist 11 or the non-illuminated photoresist 11 may be removed by a developing solution.

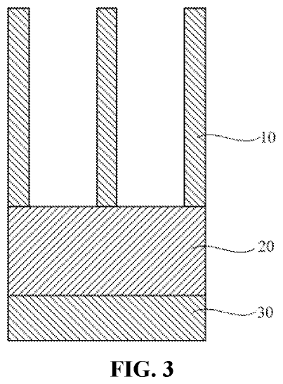

The exposed photoresist 11 is developed to form a patterned photoresist layer 10, resulting in a structure shown in FIG. 3.

During the development of the photoresist 11, the photoresist 11 is partially removed by reacting with the developing solution. Byproducts generated when the developing solution reacts with the photoresist 11 are generally accumulated on the surface of the photoresist layer 10. The byproducts may be removed by cleaning, but the byproducts may partially remain on the surface of the photoresist layer 10, thereby affecting discharge of gas in the photoresist layer 10.

In S102, the photoresist layer is treated with plasma to harden the photoresist layer, and the byproducts are at least partially removed.

In the example of the disclosure, the photoresist layer 10 is treated with plasma at a temperature of less than or equal to 100° C., and the plasma is oxygen-containing plasma. The oxygen plasma reacts with the photoresist layer 10 at a low temperature to harden the photoresist layer 10 without removing the photoresist layer 10.

It should be noted that the flow rate of the plasma may be greater than or equal to 10,000 sccm. The plasma may be oxygen plasma formed of pure oxygen, or mixed plasma including at least one of oxygen plasma, hydrogen plasma, nitrogen plasma, or chlorine plasma.

When the photoresist layer 10 is treated with plasma, the plasma has a flow rate of greater than or equal to 10,000 sccm, a power of greater than 4,000 w, and a pressure of 1-2 T (Torr). The process may be performed in a photoresist stripper.

Exemplarily, the photoresist stripper includes a reaction chamber into which oxygen is introduced after the target etching layer 30, the mask material layer 20, and the photoresist layer 10 are placed in the reaction chamber. The oxygen forms oxygen plasma under the excitation of a plasma field in the reaction chamber, or oxygen plasma is directly introduced into the reaction chamber. The photoresist layer 10 is hardened by the oxygen plasma, so that the deformation resistance, such as bending resistance and/or torsion resistance, of the photoresist layer 10 is improved, the photoresist layer 10 can well keep patterns from deforming, and the etching accuracy during subsequent dry etching is improved.

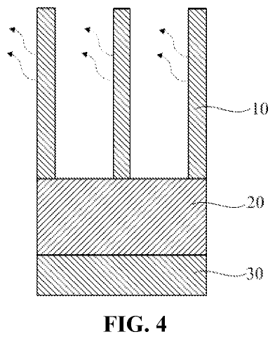

When the photoresist layer 10 is treated with plasma, the oxygen plasma also reacts with byproducts on the surface of the photoresist layer 10 to decompose the byproducts to form volatile gas, thereby removing the byproducts on the surface of the photoresist layer 10 partially or wholly, and facilitating the discharge of gas in the photoresist layer 10. The gas may be discharged in a direction indicated by an arrow in FIG. 4. In this way, the stress inside the photoresist layer 10 can be reduced, and on the other hand, the photoresist layer 10 can be further solidified, so that the deformation resistance of the photoresist layer 10 is further enhanced. It will be appreciated that some or even all of the byproducts may be removed by adjusting the type and amount of plasma in the plasma.

It should be noted that the photoresist layer 10 treated with plasma may slightly shrink, i.e. a ratio between dimension of the photoresist layer 10 treating with plasma and the photoresist layer 10 before treating with plasma is less than 1. In view of this, the photoresist layer 10 before treating with plasma may have a certain design margin so that a pattern of the photoresist layer 10 treating with plasma is consistent with the design dimension of the pattern to improve the accuracy of dry etching.

After the operation that the photoresist 11 is developed and before the operation that the photoresist layer 10 is treated with plasma, the method for treating the photoresist 11 further includes the following operations. The patterned photoresist layer 10 is baked to solidify the photoresist layer 10. The patterned photoresist layer 10 is baked at a baking temperature of less than or equal to 90° C., so that the photoresist layer 10 is polymerized, and therefore the photoresist layer 10 has good etching resistance.

In the example of the disclosure, the mask material layer 20 is disposed on the target etching layer 30, and the photoresist is disposed on the mask material layer 20. The photoresist 11 is developed, the patterned photoresist layer 10 is formed on the mask material layer 20, and then the photoresist layer 10 is treated with plasma to harden the photoresist layer 10. By hardening the photoresist layer 10 through plasma treatment, the deformation resistance of the photoresist layer 10 is enhanced. When the mask material layer 20 is dry-etched by taking the photoresist layer 10 as a mask, the photoresist layer 10 is unlikely to deform, the etching accuracy of subsequent processes is improved, and therefore the yield of semiconductor structures is improved. In addition, the byproducts are formed on the surface of the photoresist layer 10 after the photoresist 11 is developed. When the photoresist layer 10 is treated with plasma, the byproducts can be at least partially removed, so that gas in the photoresist layer 10 can be discharged, thereby reducing the stress of the photoresist layer 10, further enhancing the deformation resistance of the photoresist layer 10, and further improving the yield of semiconductor structures.

### Example 2

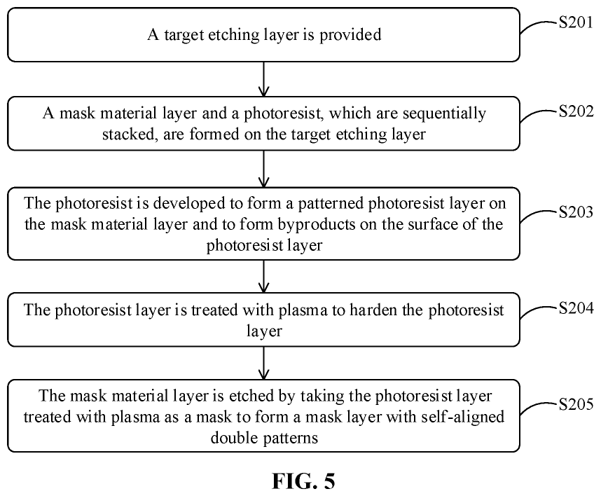

Referring to FIG. 5, the disclosure also provides an SADP method for improving the yield of semiconductor structures while improving the integration density of semiconductor structures. The SADP method specifically includes the following operations.

In S201, a target etching layer is provided.

In the example of the disclosure, a desired semiconductor structure is formed in a target etching layer 30. The target etching layer 30 is a material layer to be etched in different semiconductor structures. Exemplarily, when etching gate, the target etching layer 30 is a gate material layer on a substrate. For example, the gate material layer is a polysilicon layer. When etching a metal connecting line, the target etching layer 30 is a dielectric layer. For example, the dielectric layer is a silicon oxide layer. The metal connecting line is formed in a pattern formed by etching the dielectric layer.

In S202, a mask material layer and a photoresist, which are sequentially stacked, are formed on the target etching layer.

In the example of the disclosure, the mask material layer 20 may be a multi-layer structure, and the layers of the mask material layer 20 may be sequentially formed on the target etching layer 30 by Chemical Vapor Deposition (CVD) or Atomic Layer Deposition (ALD), etc. After the mask material layer 20 is formed, a photoresist may be coated on the mask material layer 20 by a spinning method.

In S203, the photoresist is developed to form a patterned photoresist layer on the mask material layer and to form byproducts on the surface of the photoresist layer.

It will be appreciated that before the operation that the photoresist is developed, the photoresist is also baked and exposed. The solvent in the photoresist is partially evaporated by baking, and the chemical property of the photoresist may be changed by exposure to facilitate partial removal of the photoresist by a developing solution.

The exposed photoresist is developed to form a patterned photoresist layer 10, thereby forming a desired pattern on the photoresist layer 10. During the development of the photoresist, the photoresist is partially removed by reacting with the developing solution, and byproducts generated when the developing solution reacts with the photoresist 11 are generally accumulated on the surface of the photoresist layer 10. The byproducts may be removed by cleaning, and the byproducts partially remain on the surface of the photoresist layer 10, thereby affecting discharge of gas in the photoresist layer 10.

In S204, the photoresist layer is treated with plasma to harden the photoresist layer, and the byproducts are at least partially removed.

The photoresist layer 10 is treated with plasma at a temperature of less than or equal to 100° C., and the plasma is oxygen-containing plasma. The oxygen plasma reacts with the photoresist at a low temperature to harden the photoresist without removing the photoresist layer 10. The flow rate of the plasma is greater than or equal to 10,000 sccm. The plasma may be oxygen-containing plasma, i.e. the plasma may be pure oxygen plasma or mixed plasma containing oxygen plasma.

When the photoresist layer is treated with plasma, the plasma has a flow rate of greater than or equal to 10,000 sccm, a power of greater than 4,000 w, and a pressure of 1-2 T. The process may be performed in a photoresist stripper.

When the photoresist layer is treated with plasma, the oxygen plasma may also react with byproducts on the surface of the photoresist layer 10 to decompose the byproducts to form volatile gas, thereby removing the byproducts on the surface of the photoresist layer 10 partially or wholly, facilitating the discharge of gas in the photoresist layer 10 to reduce the stress inside the photoresist layer 10, and further solidifying the photoresist layer 10 to enhance the deformation resistance of the photoresist layer 10. It will be appreciated that some or even all of the byproducts may be removed by adjusting the type and amount of plasma in the plasma.

The photoresist layer 10 treated with plasma may slightly shrink, i.e. a ratio between dimension the photoresist layer 10 after treating with plasma and the photoresist layer 10 before treating with plasma is less than 1. In view of this, the photoresist layer 10 before treating with plasma may have a certain design margin so that a design dimension of a pattern of the photoresist layer 10 after treating with plasma is consistent with that of this pattern.

After the operation that the photoresist 11 is developed, the SADP method further includes the following operation. The patterned photoresist layer 10 is baked to solidify the photoresist layer 10. The patterned photoresist layer 10 is baked at a baking temperature of less than or equal to 90° C., so that the photoresist layer 10 is polymerized, and therefore the photoresist layer 10 has good etching resistance.

In S205, the mask material layer is etched by taking the photoresist layer treated with plasma as a mask to form a mask layer with self-aligned double patterns.

The pattern of the mask layer formed in this operation is denser than that of the photoresist layer 10, and a smaller CD may be obtained by etching with the mask layer as a mask compared with etching with the photoresist layer 10 as a mask, so that the integration level of a semiconductor device is improved.

In the example of the disclosure, the operation that a mask layer with self-aligned double patterns is formed includes the following sub-operations. A side wall material layer is formed on the mask material layer 20, and then the mask material layer 20 and the side wall material layer are partially removed. For example, the mask material layer 20 and the side wall material layer are dry-etched. The side wall material layer on a side face of the mask material layer 20 before the removal is reserved. The reserved side wall material layer has self-aligned double patterns.

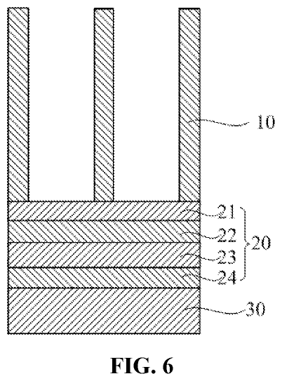

In some possible examples, as shown in FIG. 6, the mask material layer 20 includes a first hard mask layer 24, a first anti-reflection layer 23, a second hard mask layer 22, and a second anti-reflection layer 21, which are sequentially stacked. The first hard mask layer 24 is close to the target etching layer 30. The second anti-reflection layer 21 is close to the photoresist layer 10.

The first hard mask layer 24 and the second hard mask layer 22 serve to transfer patterns. The first hard mask layer 24 and the second hard mask layer 22 may be amorphous carbon (a-C) layers or polysilicon layers. The first anti-reflection layer 23 and the second anti-reflection layer 21 serve to reduce reflection in etching, and may be dielectric materials. For example, the first anti-reflection layer 23 and the second anti-reflection layer 21 are silicon oxynitride (SiON) layers, and the first anti-reflection layer 23 may be thicker than the second anti-reflection layer 21.

When the mask material layer 20 has the above structure, the operation that the mask material layer 20 is etched by taking the photoresist layer 10 treated with plasma as a mask to form a mask layer with self-aligned double patterns includes the following sub-operations.

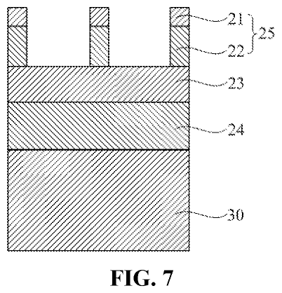

Firstly, the second anti-reflection layer 21 and the second hard mask layer 22 are partially removed by taking the photoresist layer 10 treated with plasma as a mask. The second anti-reflection layer 21 and the second hard mask layer 22 covered by the photoresist layer 10 are reserved. A sacrificial layer 25 is formed by the reserved second anti-reflection layer 21 and the second hard mask layer 22, thereby forming a structure shown in FIG. 7.

Exemplarily, the second anti-reflection layer 21 and the second hard mask layer 22 are dry-etched, parts of the second anti-reflection layer 21 and the second hard mask layer 22 covered by the photoresist layer 10 are reserved, and other parts are removed. The etching gas may be NF3, CH3F, CHF3, N2, etc.

It should be noted that the photoresist layer 10 may be removed by ashing after etching the second anti-reflection layer 21 and the second hard mask layer 22. It is also possible to etch the second anti-reflection layer 21 by taking the photoresist layer 10 as a mask and then remove the photoresist layer 10 while etching the second hard mask layer 22.

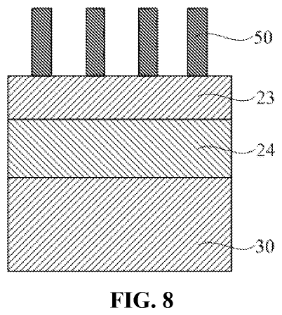

Then, after the sacrificial layer 25 is formed, a side wall material layer 40 is formed on the sacrificial layer 25. The sacrificial layer 25 and the side wall material layer 40 are partially removed. The side wall material layer 40 on the side face of the sacrificial layer 25 before the removal is reserved. A side wall 50 is formed by the reserved side wall material layer 40, thereby forming a structure as shown in FIG. 8.

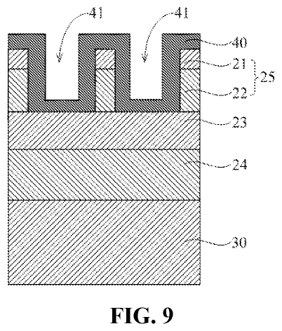

Exemplarily, the side wall material layer 40 may be formed on the sacrificial layer 25 by ALD to form a structure shown in FIG. 9. The side wall material layer 40 may be a silicon oxide layer, and the dimension of an etching groove 41 can be controlled by controlling the thickness of the side wall material layer 40 to adjust a distance between the side walls 50 formed in subsequent processes, thereby controlling the CD of the mask layer.

After the side wall material layer 40 is formed, the side wall material layer 40 may be partially removed by dry etching. The side wall material layer 40 on the side face of the sacrificial layer 25 is reserved, and the remaining sacrificial layer 25 is removed. The side wall 50 is formed by the reserved side wall material layer 40.

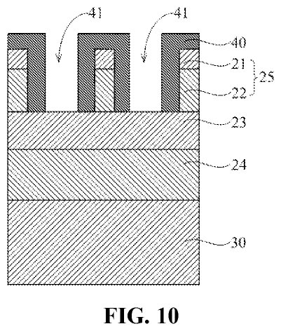

Exemplarily, the side wall material layer 40 in the etching groove 41 may be removed by dry etching to form a structure shown in FIG. 10. Then, the side wall material layer 40 at the top of the sacrificial layer 25 is removed by dry etching, or the side wall material layer 40 at the top of the sacrificial layer 25 is planarized by Chemical Mechanical Polish (CMP) so as to expose the second hard mask layer 22. Then, the sacrificial layer 25 formed by the second hard mask layer 22 and the second anti-reflection layer 21 is removed to reserve the side wall material layer 40 on the side face of the sacrificial layer 25.

It should be noted that also, the side wall material layer 40 above the sacrificial layer 25 and the side wall material layer 40 in the etching groove 41 may be removed simultaneously by dry etching, and then the sacrificial layer 25 is removed by dry etching. For example, components of a layer to be etched in an etching process are detected. When an element in the second hard mask layer 22 is detected, the etching gas is switched, thereby removing the second hard mask layer 22 and the second anti-reflection layer 21.

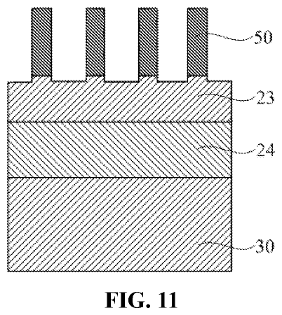

In the process of forming the side wall 50, when the sacrificial layer 25 is removed by etching, etching is stopped till the first anti-reflection layer 23. Also, as shown in FIG. 11, the first anti-reflection layer 23 in the etching groove 41 may be partially removed by etching.

Finally, after the side wall 50 is formed, the first anti-reflection layer 23 and the first hard mask layer 24 are partially removed by taking the side wall 50 as a mask. The first hard mask layer 24 covered by the side wall 50 is reserved. A mask layer with self-aligned double patterns is formed by the reserved first hard mask layer 24.

In the example of the disclosure, according to the SADP method, the target etching layer 30 is provided. Then, the mask material layer 20 and the photoresist, which are sequentially stacked, are formed on the target etching layer 30. Then, the photoresist is developed to form the patterned photoresist layer 10 on the mask material layer 20 and to form the byproducts on the surface of the photoresist layer 10. Thereafter, the photoresist layer 10 is treated with plasma to harden the photoresist layer 10. Finally, the mask material layer 20 is etched by taking the photoresist layer 10 treated with plasma as a mask to form a mask layer with self-aligned double patterns. By treating the photoresist layer 10 with plasma and hardening the photoresist layer 10 through plasma treatment, the deformation resistance of the photoresist layer 10 is improved. When the mask material layer 20 is etched by taking the photoresist layer 10 as a mask, the photoresist layer 10 is unlikely to deform, the etching accuracy of subsequent processes is improved, and therefore the yield of semiconductor structures is improved. In addition, byproducts are formed on the surface of the photoresist layer 10 after the photoresist is developed. When the photoresist layer 10 is treated with plasma, the byproducts on the surface of the photoresist layer 10 can be at least partially removed, so that gas in the photoresist layer 10 can be discharged, thereby reducing the stress of the photoresist layer 10, further enhancing the deformation resistance of the photoresist layer 10, and improving the yield of semiconductor structures.

The examples or implementations described in this specification are described in an incremental manner, with each example being described with emphasis on differences from the other examples, and with reference to like parts throughout the various examples.

Those skilled in the art will appreciate that in the disclosure of the present application, orientation or positional relationships indicated by the terms “longitudinal”, “transverse”, “above”, “below”, “front”, “rear”, “left”, “right”, “vertical”, “horizontal”, “top”, “bottom”, “in”, “out”, etc. are based on the orientation or positional relationships shown in the drawings, which are merely intended to facilitate describing the disclosure and to simplify the description rather than indicating or implying that the referenced system or element must have a particular orientation and be constructed and operated in a particular orientation. Therefore, the above terms are not to be construed as limiting the disclosure.

In the descriptions of this specification, the description with reference to the terms “one embodiment”, “some embodiments”, “exemplary embodiments”, “example”, “specific example”, or “some examples”, etc. means that particular features, structures, materials, or characteristics described in conjunction with the embodiment or example are included in at least one embodiment or example of the disclosure. In this specification, schematic representations of the above terms do not necessarily refer to the same embodiment or example. Furthermore, the particular features, structures, materials, or characteristics described may be combined in any suitable manner in any one or more embodiments or examples.

Finally, it should be noted that the above examples are merely illustrative of the technical solutions of the disclosure and are not intended to be limiting thereof. Although the disclosure has been described in detail with reference to the foregoing examples, those of ordinary skill in the art will appreciate that the technical solutions of the foregoing examples may still be modified, or some or all of the technical features thereof may be equivalently replaced. These modifications or replacements do not make the essence of the corresponding technical solutions depart from the scope of the technical solutions of the various examples of the disclosure.

1. A method for treating a photoresist, wherein the photoresist is disposed on a mask material layer and the mask material layer is disposed on a target etching layer, the method comprising:
developing the photoresist to form a patterned photoresist layer on the mask material layer and to form byproducts on a surface of the photoresist layer; and
treating the photoresist layer with plasma to harden the photoresist layer.

2. The method of claim 1, wherein the treating the photoresist layer with plasma is performed at a temperature of less than or equal to 100° C.

3. The method of claim 1, wherein the plasma is oxygen-containing plasma.

4. The method of claim 1, wherein the plasma has a flow rate of greater than or equal to 10,000 sccm.

5. The method of claim 1, after the developing the photoresist and before the treating the photoresist layer with plasma, further comprising:
baking the patterned photoresist layer to solidify the photoresist layer.

6. The method of claim 5, wherein the baking the patterned photoresist layer is performed at a baking temperature of less than or equal to 90° C.

7. The method of claim 1, wherein a ratio between dimension of the photoresist layer after treating with plasma and dimension of the photoresist layer before treating with plasma is less than 1.

8. A self-aligned double patterning method, comprising:
providing a target etching layer;
forming a mask material layer and a photoresist, which are sequentially stacked, on the target etching layer;
developing the photoresist to form a patterned photoresist layer on the mask material layer and to form byproducts on a surface of the photoresist layer;
treating the photoresist layer with plasma to harden the photoresist layer; and
etching the mask material layer by taking the photoresist layer treated with plasma as a mask to form a mask layer with self-aligned double patterns.

9. The self-aligned double patterning method of claim 8, wherein the etching the mask material layer by taking the photoresist layer treated with plasma as a mask to form a mask layer with self-aligned double patterns comprises:
forming a side wall material layer on the mask material layer, partially removing the mask material layer and the side wall material layer to reserve the side wall material layer located on a side face of the mask material layer before the removal, the reserved side wall material layer having self-aligned double patterns.

10. The self-aligned double patterning method of claim 8, wherein the mask material layer comprises a first hard mask layer, a first anti-reflection layer, a second hard mask layer, and a second anti-reflection layer, which are sequentially stacked, the first hard mask layer being close to the target etching layer;
the etching the mask material layer by taking the photoresist layer treated with plasma as a mask to form a mask layer with self-aligned double patterns comprises:
partially removing the second anti-reflection layer and the second hard mask layer by taking the photoresist layer treated with plasma as a mask to reserve the second anti-reflection layer and the second hard mask layer covered by the photoresist layer, and forming a sacrificial layer by the reserved second anti-reflection layer and the second hard mask layer;
forming a side wall material layer on the sacrificial layer, partially removing the sacrificial layer and the side wall material layer to reserve the side wall material layer located on a side face of the sacrificial layer before the removal, and forming a side wall by the reserved side wall material layer; and
partially removing the first anti-reflection layer and the first hard mask layer by taking the side wall as a mask to reserve the first hard mask layer covered by the side wall, and forming a mask layer with self-aligned double patterns by the reserved first hard mask layer.

11. The self-aligned double patterning method of claim 10, wherein the first anti-reflection layer and the second anti-reflection layer are silicon oxynitride layers, and the side wall material layer is an oxide layer.
